(19) United States
(12) Patent Application Publication
(10) Pub. No.: US 2026/0206333 A1
(43) Pub. Date: Jul. 16, 2026

(54) SEMICONDUCTOR STRUCTURE AND METHODS OF MAKING SAME

(71) Applicant: TAIWAN SEMICONDUCTOR MANUFACTURING COMPANY LTD., HSINCHU (TW)

(72) Inventors: WEN-SHUN LO, HSINCHU COUNTY (TW); TSUNG-LIN HSIEH, HSINCHU CITY (TW); CHUN-HENG CHEN, HSINCHU CITY (TW); KAI-QIANG WEN, HSINCHU (TW); CHI-YUAN SHIH, HSINCHU (TW); YINGKIT FELIX TSUI, CUPERTINO, CA (US)

(21) Appl. No.: 19/017,834

(22) Filed: Jan. 13, 2025

(51) Int. Cl. H10F 30/22; G02B 6/12; G02B 6/122; G02B 6/136; G02B 6/42; H10F 71/00; H10F 77/40

(52) U.S. Cl. CPC H10F 30/22; G02B 6/1228; G02B 6/136; G02B 6/4201; H10F 71/121; H10F 77/413; G02B 2006/12173

(57) ABSTRACT

A semiconductor structure is provided. The semiconductor structure includes a waveguide region and a photodetector. The waveguide region is formed over a base layer and includes an optical coupling portion. The optical coupling portion includes a base portion sandwiched by two elongated portions and including a front edge, a middle portion and a rear edge. The photodetector is formed on the middle portion of the base portion of the waveguide region and includes a front side abutting the front edge of the base portion and a rear side abutting the rear edge of the base portion. A distance between a top of the front edge of the base portion and a bottom of the front side of the photodetector is less than a distance between a top of the rear edge of the base portion and a bottom of the rear side of the photodetector.

### BACKGROUND

Silicon photonic devices can be made using existing semiconductor fabrication techniques, and because silicon is already used as the substrate for most integrated circuits, it is possible to create hybrid devices in which the optical and electronic components are integrated onto a single microchip. Consequently, silicon photonics is being actively researched by many electronics manufacturers, as well as by academic research groups, as a means for keeping on track with Moore's Law, by using optical interconnects to provide faster data transfer both between and within microchips.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a top view of a semiconductor structure, in accordance with some embodiments of the present disclosure.

FIG. 2 illustrates a cross-sectional front view along line B-B′ of the semiconductor structure shown in FIG. 1, in accordance with some embodiments of the present disclosure.

FIGS. 3 to 8 illustrate cross-sectional side views along line C-C′ of the semiconductor structure shown in FIG. 1, in accordance with various embodiments of the present disclosure.

FIG. 9A is a plot of an optical intensity as a function of length of a photodetector of a semiconductor structure.

FIG. 9B is a plot of an amount of electron and hole pairs as a function of length of a photodetector of a semiconductor structure.

FIG. 10 is a flowchart of a method for forming the semiconductor structure in accordance with some embodiments.

FIGS. 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, 20C, 21A, 21B, 21C, 22A, 22B, 22C, 23A, 23B, 23C, 24A, 24B, 24C, 25A, 25B and 25C illustrate various cross-sectional views of forming the semiconductor structure in accordance with some embodiments as described in FIG. 10, in which 11A, 12A, 13A, 14A, 15A, 16A, 17A, 18A, 19A, 20A, 21A, 22A, 23A, 24A and 25A are cross-sectional views of the semiconductor structure corresponding to the cross-section along line A-A′ shown in FIG. 1; 11B, 12B, 13B, 14B, 15B, 16B, 17B, 18B, 19B, 20B, 21B, 22B, 23B, 24B and 25B are cross-sectional views of the semiconductor structure corresponding to the cross-section along line B-B′ shown in FIG. 1; and 11C, 12C, 13C, 14C, 15C, 16C, 17C, 18C, 19C, 20C, 21C, 22C, 23C, 24C and 25C are cross-sectional views of the semiconductor structure corresponding to the cross-section along line C-C′ shown in FIG. 1.

### DETAILED DESCRIPTION OF THE DISCLOSURE

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 100 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

The present disclosure relates to photonic devices which are made up of different layers. When the terms “on” or “upon” are used with reference to two different layers (including the substrate), they indicate merely that one layer is on or upon the other layer and do not require the two layers to directly contact each other, and permit other layers to be between the two layers. For example, all layers of the photonic device can be considered to be “on” the substrate, even though they do not all directly contact the substrate. The term “directly” may be used to indicate two layers directly contact each other without any layers in between them. Similarly, the terms “input” and “output” are relative to light passing through them with respect to a given structure, e.g. light enters the structure through the input, and exits the structure through the output.

Photonic structure is a promising platform for the construction of efficient information processing chips due to its compatibility to complementary-metal-oxide semiconductor (CMOS) technology, and with benefits of low cost, and high yield. A photodetector can be used in a photonic structure to detect optical signals. For a typical photodetector, the photocurrent initially increases as the optical input power increases and then gradually saturates. However, the increasing photocurrent would lead reduction in 3-db bandwidth and thus decrease the detection speed of the photodetector. That is, it is difficult to achieve high bandwidth with high optical power. There is a need to obtain a high-speed and high-power photodetector to enhance performance of the photonic structure.

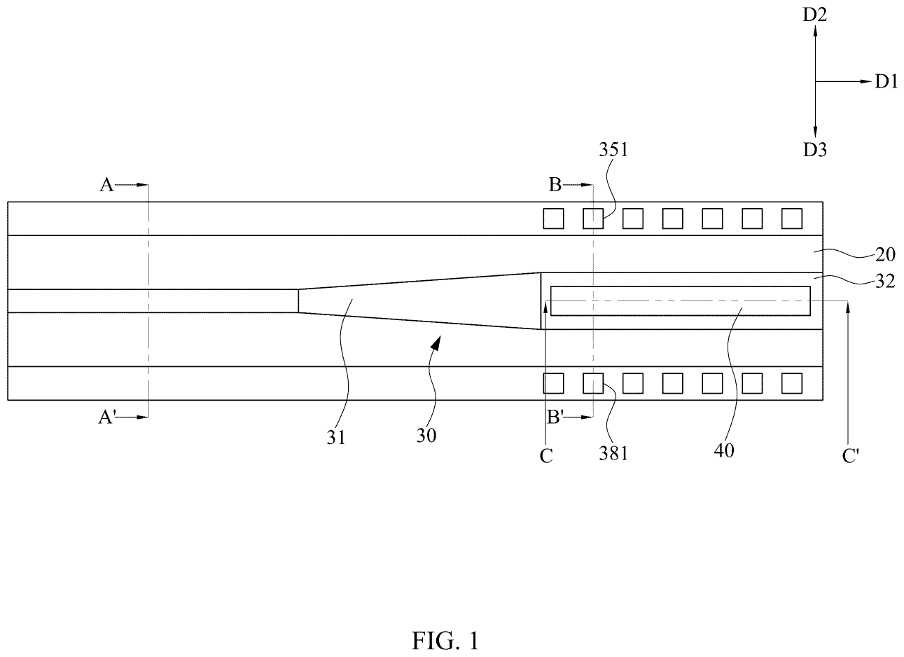

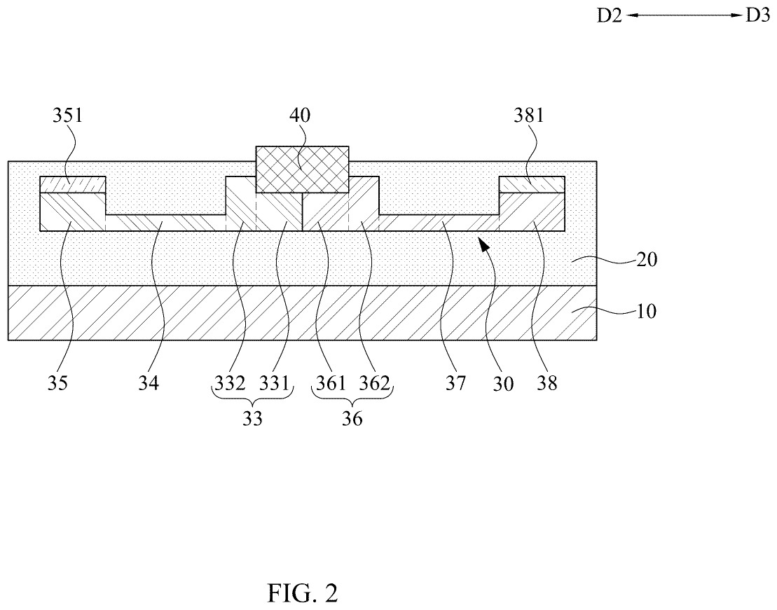

FIG. 1 illustrates a top view of a semiconductor structure in accordance with some embodiments of the present disclosure and FIG. 2 illustrates a cross-sectional front view along line B-B′ of the semiconductor structure shown in FIG. 1. The semiconductor structure comprises a base layer 10, a cladding layer 20 formed on the base layer 10, a waveguide 30 and a photodetector 40.

The base layer 10 is usually a wafer made of a semiconducting material. Such materials can include silicon, for example in the form of monocrystalline Si or polycrystalline Si. The base layer 10 can also be made from other elementary semiconductors such as germanium or Al₂O₃ (sapphire), or may include a compound semiconductor such as silicon carbide (SiC), gallium nitride (GaN), gallium arsenide (GaAs), indium arsenide (InAs), and indium phosphide (InP), or from other materials such as glass, a ceramic, or a dielectric material. In some embodiments, the substrate may be a silicon-on-insulator (SOI) wafer. An SOI wafer comprises a substrate and an insulating layer (e.g., buried oxide or BOX) formed on the substrate.

The cladding layer 20 is overlaid onto the base layer 10 and may include a dielectric material, such as silicon oxide. The material forming the cladding layer 20 may be identical to that forming the buried oxide of the insulating layer of the SOI wafer. In some embodiments, the cladding layer 20 may include oxide and serve as the buried oxide of the insulating layer of the SOI wafer.

The waveguide 30 comprises a core region 31 and a waveguide region 32. The core region 31 is formed in the cladding layer 20 and comprises a semiconductor material, such as silicon. The core region 31 is located at a front end of the waveguide 30 to receive incident light beam. The core region 31 may have a top section with a tapered shape, such as trapezoid and in some embodiments, with an isosceles trapezoid shape. The core region 31 has a proximal end receiving the incident light beam and a distal end adjacent to the waveguide region 32.

The waveguide region 32 is formed in the cladding layer 20 and comprises a semiconductor material, such as silicon. The waveguide region 32 is extended from the distal end of the core region 31 along a first direction D1. As shown in FIG. 2, the waveguide region 32 comprises a first optical coupling portion 33, a first slab portion 34, a first electrical coupling portion 35, a second optical coupling portion 36, a second slab portion 37 and a second electrical coupling portion 38. The first optical coupling portion 33, the first slab portion 34, the first electrical coupling portion 35, the second optical coupling portion 36, the second slab portion 37 and the second electrical coupling portion 38 are strips parallel to each other. The first optical coupling portion 33, the first slab portion 34 and the first electrical coupling portion 35 comprise silicon and dopants with a first conductivity type. The second optical coupling portion 36, the second slab portion 37 and the second electrical coupling portion 38 comprise silicon and dopants with a second conductivity type. When the first conductivity type is n type, the second conductivity type is p type; and when the first conductivity type is p type, the second conductivity type is n type. Any suitable P-type dopant may be used, such as one or more of boron (B), gallium (Ga), or indium (In), any suitable N-type dopant may be used, such as one or more of phosphorous (P), arsenic (As), antimony (Sb), bismuth (Bi), lithium (Li), etc.

The first optical coupling portion 33 and the second optical coupling portion 36 abut each other. The first optical coupling portion 33 has an L-shape cross-section from the front view and comprises a first base portion 331 and a first elongated portion 332. The first elongated portion 332 is extended from the first base portion 331 along a second direction D2 perpendicular to the first direction D1. A thickness of the first elongated portion 332 is greater than a thickness of the first base portion 331. The first slab portion 34 is extended from the first elongated portion 332 of the first optical coupling portion 33 along the second direction D2. The first electrical coupling portion 35 is extended from the first slab portion 34 along the second direction D2. An upper region of the first electrical coupling portion 35 can be a first heavily-doped region 351. A top of the first elongated portion 332 of the first optical coupling portion 33 may be substantially coplanar with a top of the first electrical coupling portion 35 (i.e., a top of the first heavily-doped region 351). A bottom of the first base portion 331 may be substantially coplanar with a bottom of the first elongated portion 332, a bottom of the first slab portion 34 and a bottom of the first electrical coupling portion 35. The thickness of the elongated portion 332 of the first optical coupling portion 33 is greater than a thickness of the first slab portion 34. The thickness of the first elongated portion 332 of the first optical coupling portion 33 may be substantially identical to a thickness of the first electrical coupling portion 35. The thickness of the first electrical coupling portion 35 is greater than the thickness of the first slab portion 34. In some embodiments, the thickness of the first base portion 331 is greater than the thickness of the first slab portion 34.

The second optical coupling portion 36 has a reversed L-shape cross-section from the front view, which mirrors the L-shape cross-section of the first optical coupling portion 311. The second optical coupling portion 36 comprises a second base portion 361 and a second elongated portion 362. The second elongated portion 362 is extended from the second base portion 361 along a third direction D3 perpendicular to the first direction D1 and opposite to the second direction D2. A thickness of the second elongated portion 362 is greater than a thickness of the second base portion 361. The second slab portion 37 is extended from the second elongated portion 362 of the second optical coupling portion 36 along the third direction D3. The second electrical coupling portion 38 is extended from the second slab portion 37 along the third direction D3. An upper region of the second electrical coupling portion 38 can be a second heavily doped region 381. A top of the second elongated portion 362 of the second optical coupling portion 36 may be substantially coplanar with a top of the second electrical coupling portion 38 (i.e., a top of the first heavily-doped region 381). A bottom of the second base portion 361 may be substantially coplanar with a bottom of the second elongated portion 362, a bottom of the second slab portion 37 and a bottom of the second electrical coupling portion 38. A thickness of the second optical coupling portion 36 is greater than a thickness of the second slab portion 37. The thickness second elongated portion 362 of the second optical coupling portion 36 may be substantially identical to a thickness of the second electrical coupling portion 38. The thickness of the second electrical coupling portion 38 is greater than the thickness of the second slab portion 37.

A configuration of the first optical coupling portion 33, the first slab portion 34, and the first electrical coupling portion 35 may be symmetric or asymmetric to that of the second optical coupling portion 36, the second slab portion 37 and the second electrical coupling portion 38. In some embodiments, a configuration of the first slab portion 34, and the first electrical coupling portion 35 is symmetric to that of the second optical coupling portion 36, the second slab portion 37 and the second electrical coupling portion 38 as shown in FIG. 2. The thickness of the first base portion 331 of the first optical coupling portion 33 may be substantially identical to the thickness of the second base portion 361 of the second optical coupling portion 36. The thickness of the first elongated portion 332 of the first optical coupling portion 33 may be substantially identical to the thickness of the second elongated portion 362 of the second optical coupling portion 36. The thickness of the first slab portion 34 may be substantially identical to the thickness of the second slab portion 37. The thickness of the first electrical coupling portion 35 may be substantially identical to the thickness of second electrical coupling portion 38.

The photodetector 40 is formed in the first optical coupling portion 33 and the second optical coupling portion 36 of the waveguide 30. The photodetector 40 can be formed on the first base portion 331 of the first optical coupling portion 33 and on the second base portion 361 of th second optical coupling portion 36. A lower portion of the photodetector 40 can be surrounded by the first optical coupling portion 33 and the second optical coupling portion 36 of the waveguide 30.

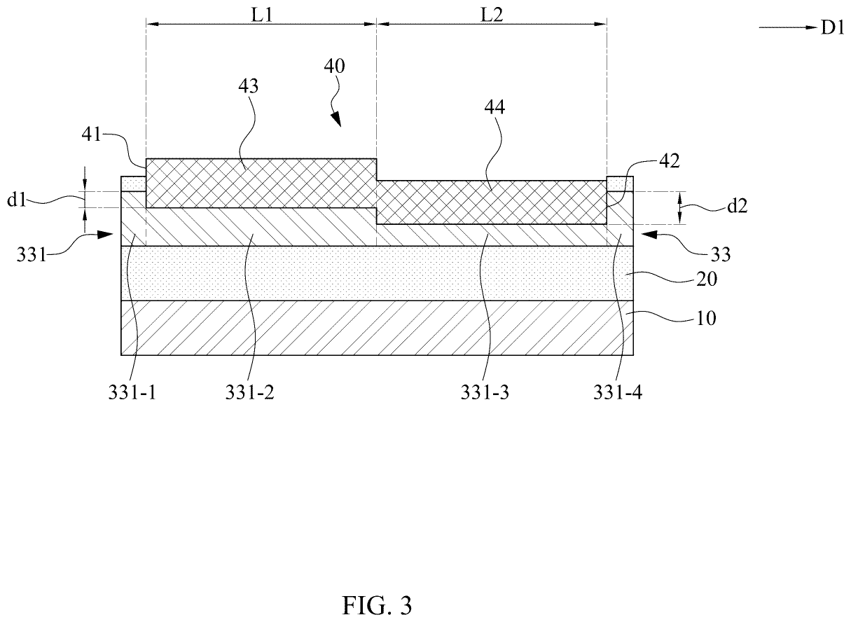

In some embodiments with reference to FIG. 3 showing a cross-sectional side view along line C-C′ of the semiconductor structure shown in FIG. 1, the first base portion 331 of the first optical coupling portion 33 has a front edge 331-1, a first middle portion 331-2, a second middle portion 331-3 and a rear edge 331-4. A thickness of the front edge 331-1 can be greater than a thickness of the first middle portion 331-2. The thickness of the first middle portion 331-2 can be greater than a thickness of the second middle portion 331-3. A thickness of the rear edge 331-4 can be greater than the thickness of the second middle portion 331-3. The thickness of the front edge 331-1 may be substantially identical to the thickness of the rear edge 331-4. A top of the front edge 331-1 may be substantially coplanar with a top of the rear edge 331-4. Therefore, the front edge 331-1, the first middle portion 331-2 and the second middle portion 331-3 are staircases with gradually decreased thicknesses. The second base portion 361 o f the second optical coupling portion 36 has a configuration substantially identical to or similar with the first base portion 331 of the first optical coupling portion 33, so FIG. 3 may also apply to showing the cross-sectional side view of the second base portion 361. Therefore, a drawing showing the cross-sectional side view of the second base portion 361 is omitted.

The photodetector 40 may comprise germanium (Ge). The photodetector 40 has a front side 41 abutting the front edge 331-1 of the first base portion 331 and a front edge of the second base portion 361, a rear side 42 abutting the rear edge 331-4 of the first base portion 331 and a rear edge of the second base portion 361, and two sides respectively abutting the first elongated portion 332 and the second elongated portion 362. The photodetector 40 comprises a front region 43 and a rear region 44. The front region 43 of the photodetector 40 is deposited on the first middle portion 331-2. The rear region 44 is extended from the front region 43 and is deposited on the second middle portion 331-3. A thickness of the front region 43 may be substantially identical to a thickness of the rear region 44. Therefore, the front region 43 and the rear region 44 are staircases corresponding to the staircase configuration formed by the first middle portion 331-2 and the second middle portion 331-3.

In some embodiments, a length of the front region 43 may be substantially identical to a length of the rear region 44. In some embodiments, the length of the front region 43 may be less than the length of the rear region 44. A ratio of the length of the front region 43 to the length of the rear region 44 may range from about 1:5 to about 4:5. In some embodiments, the ratio of the length L1 of the front region 43 to the length L2 of the rear region 44 may range from 3:10 to about 7:10. In some embodiments, the ratio of the length of the front region 43 to the length of the rear region 44 may range from about 2:5 to about 3:5. A first distance d1 between the top of the front edge 331-1 and a bottom of the first base portion 331 is less than a second distance d2 between the top of the rear edge 331-4 and a bottom of the rear region 44. In some embodiments, a ratio of the first distance d1 to the second distance d2 may be from about 1:5 to about 4:5. In some embodiments, the ratio of the first distance d1 to the second distance d2 may be from about 3:10 to about 7:10. In some embodiments, the ratio of the first distance d1 to the second distance d2 may be from about 2:5 to about 3:5.

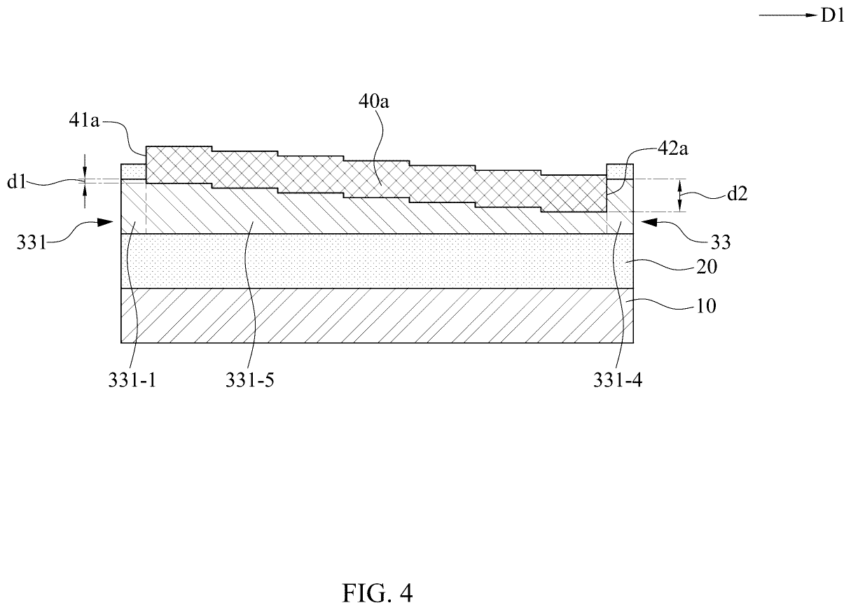

FIG. 4 shows a cross-sectional side view of the semiconductor structure in accordance with some another embodiments of the present disclosure. The first base portion 331 of the first optical coupling portion 33 has a front edge 331-1, a staircase middle portion 331-5 and a rear edge 331-4. The staircase middle portion 331-5 has a staircase top and a substantially flat bottom, so a thickness of the staircase middle portion 331-5 gradually decreases from a position near the front edge 331-1 to a position near the rear edge 331-4. A thickness of the front edge 331-1 can be greater than a greatest thickness of the first middle portion 331-2. The thickness of the front edge 331-1 may be substantially identical to a thickness of the rear edge 331-4. A top of the front edge 331-1 may be substantially coplanar with a top of the rear edge 331-4. Therefore, the front edge 331-1 and the staircase middle portion 331-5 are staircases with gradually decreased thicknesses. Also, the second base portion 361 of the second optical coupling portion 36 has a configuration substantially identical to or similar with the first base portion 331 of the first optical coupling portion 33, so FIG. 4 may also apply to showing the cross-sectional side view of the second base portion 361. Therefore, a drawing showing the cross-sectional side view of the second base portion 361 is omitted.

The photodetector 40a is deposited on the staircase middle portion 331-5 and also takes the form of a staircase with multiple steps corresponding to the staircase top of the staircase middle portion 331-5. Thicknesses of the steps of the photodetector 40a may be substantially identical to each other. The photodetector 40a has a front side 41a abutting the front edge 331-1 of the first base portion 331 and a front edge of the second base portion 361 and a rear side 42b abutting the rear edge 331-4 of the first base portion 331 and a rear edge of the second base portion 361. A first distance d1 between the top of the front edge 331-1 and a bottom of the front side 41a is less than a second distance d2 between the top of the rear edge 331-4 and a bottom of the rear side 42b. In some embodiments, a ratio of the first distance d1 to the second distance d2 may be from about 1:5 to about 4:5. In some embodiments, the ratio of the first distance d1 to the second distance d2 may be from about 3:10 to about 7:10. In some embodiments, the ratio of the first distance d1 to the second distance d2 may be from about 2:5 to about 3:5.

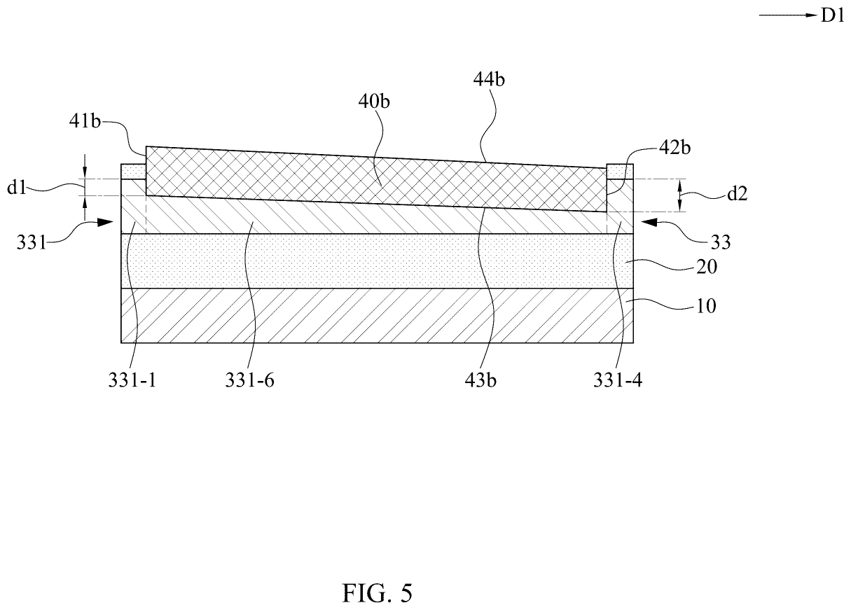

FIG. 5 shows a cross-sectional side view of the semiconductor structure in accordance with some another embodiments of the present disclosure. The first base portion 331 of the first optical coupling portion 33 has a front edge 331-1, a slope portion 331-6 and a rear edge 331-4. The slope portion 331-6 has a front side abutting the front edge 331-1 and a rear side abutting the rear edge 331-4. The slope portion 331-6 has a gradually decreased thickness from the front side to the rear side. A thickness of the front edge 331-1 can be greater than a thickness of the front side of the slope portion 331-6. A thickness of the rear edge 331-4 can be greater than a thickness of the rear side of the slope portion 331-6. The thickness of the front edge 331-1 may be substantially identical to a thickness of the rear edge 331-4. A top of the front edge 331-1 may be substantially coplanar with a top of the rear edge 331-4. Also, the second base portion 361 of the second optical coupling portion 36 has a configuration substantially identical to or similar with the first base portion 331 of the first optical coupling portion 33, so FIG. 5 may also apply to showing the cross-sectional side view of the second base portion 361. Therefore, a drawing showing the cross-sectional side view of the second base portion 361 is omitted.

The photodetector 40b is deposited on the slope portion 331-6 and has a front side 41b abutting the front edge 331-1 of the first base portion 331 and a front edge of the second base portion 361, and a rear side 42b abutting the rear edge 331-4 of the first base portion 331 and a rear edge of the second base portion 361. The photodetector 40b further has a slope bottom 43b and a slope top 44b. In some embodiments, the slope bottom 43b may be substantially parallel to the slope top 44b so that the thickness of the photodetector 40b may be substantially identical. In some embodiments, the slope bottom 43b may be not parallel to the slope top 44b. A first distance d1 between the top of the front edge 331-1 and a bottom of the front side 41b is less than a second distance d2 between the top of the rear edge 331-4 and a bottom of the rear side 42b. In some embodiments, a ratio of the first distance d1 to the second distance d2 may be from about 1:5 to about 4:5. In some embodiments, the ratio of the first distance d1 to the second distance d2 may be from about 3:10 to about 7:10. In some embodiments, the ratio of the first distance d1 to the second distance d2 may be from about 2:5 to about 3:5.

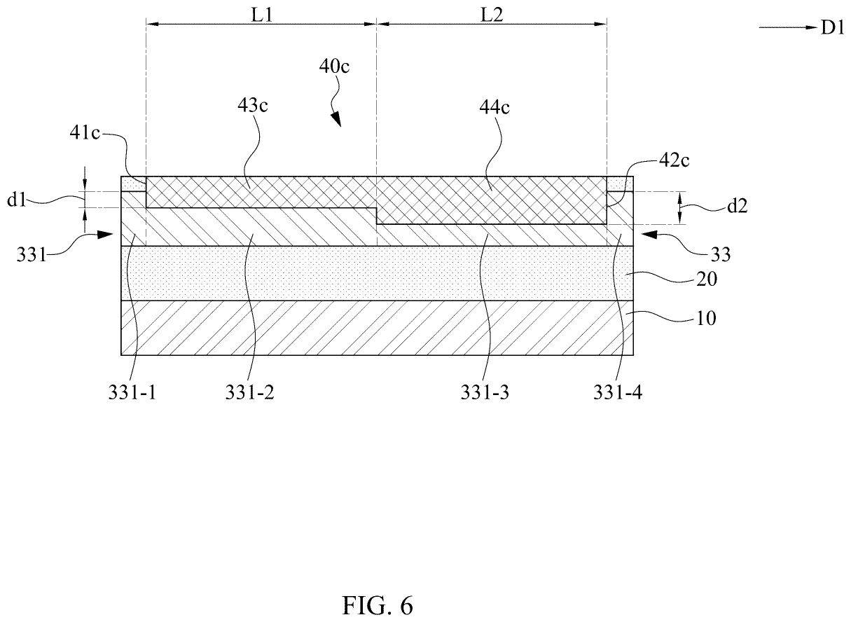

FIG. 6 shows a cross-sectional side view of the semiconductor structure in accordance with some another embodiments of the present disclosure. The configuration of the optical coupling portion 33 in the embodiments shown in FIG. 6 is substantially identical to that shown in FIG. 3; therefore those details are omitted in the interest of brevity. The photodetector 40c has a front side 41c abutting the front edge 331-1 of the first base portion 331 and a front edge of the second base portion 361, and a rear side 42c abutting the rear edge 331-4 of the first base portion 331 and a rear edge of the second base portion 361. The photodetector 40c comprises a front region 43c and a rear region 44c. The front region 43c of the photodetector 40c is deposited on the first middle portion 331-2. The rear region 44c is extended from the front region 43c and is deposited on the second middle portion 331-3. A top of the front region 43c can be substantially coplanar with a top of the rear region 44c. Therefore, a thickness of the front region 43c can be less than a thickness of the rear region 44c. A first distance d1 between the top of the front edge 331-1 and a bottom of the front region 43c is less than a second distance d2 between the top of the rear edge 331-4 and a bottom of the rear region 44c. In some embodiments, a ratio of the first distance d1 to the second distance d2 may be from about 1:5 to about 4:5. In some embodiments, the ratio of the first distance d1 to the second distance d2 may be from about 3:10 to about 7:10. In some embodiments, the ratio of the first distance d1 to the second distance d2 may be from about 2:5 to about 3:5.

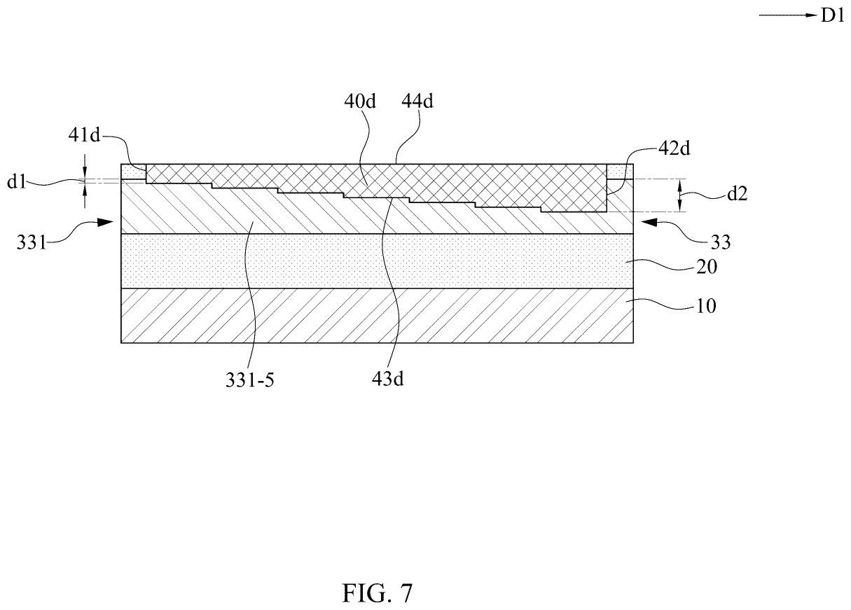

FIG. 7 shows a cross-sectional side view of the semiconductor structure in accordance with some another embodiments of the present disclosure. The configuration of the optical coupling portion 33 in the embodiments shown in FIG. 7 is substantially identical to that shown in FIG. 4; therefore those details are omitted in the interest of brevity. The photodetector 40d is deposited on the staircase middle portion 331-5 and thus has a staircase bottom 43d with multiple steps corresponding to the staircase top of the staircase middle portion 331-5. The photodetector 40d has a front side 41d abutting the front edge 331-1 of the first base portion 331 and a front edge of the second base portion 361, and a rear side 42d abutting the rear edge 331-4 of the first base portion 331 and a rear edge of the second base portion 361. The photodetector 40 d has a substantially flat top 44d. Thickness of the photodetector 40a may be stepwisely increased from the front side 41d to the rear side 42d. A first distance d1 between the top of the front edge 331-1 and a bottom of the front side 41d is less than a second distance d2 between the top of the rear edge 331-4 and a bottom of the rear side 42d. In some embodiments, a ratio of the first distance d1 to the second distance d2 may be from about 1:5 to about 4:5. In some embodiments, the ratio of the first distance d1 to the second distance d2 may be from about 3:10 to about 7:10. In some embodiments, the ratio of the first distance d1 to the second distance d2 may be from about 2:5 to about 3:5.

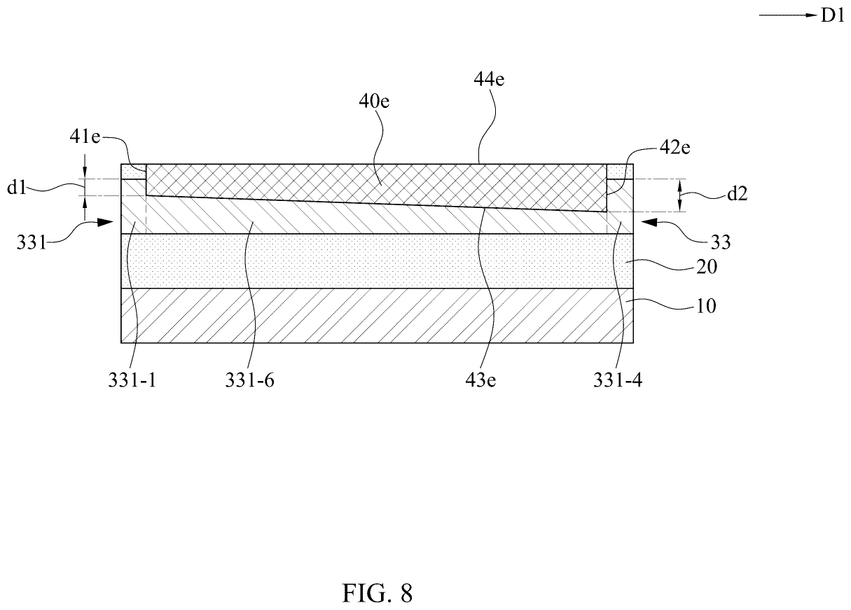

FIG. 8 shows a cross-sectional side view of the semiconductor structure in accordance with some another embodiments of the present disclosure. The configuration of the optical coupling portion 33 in the embodiments shown in FIG. 8 is substantially identical to that shown in FIG. 5; therefore those details are omitted in the interest of brevity. The photodetector 40e is deposited on the slope portion 331-6 and has a front side 41e abutting the front edge 331-1 of the first base portion 331 and a front edge of the second base portion 361, and a rear side 42e abutting the rear edge 331-4 of the first base portion 331 and a rear edge of the second base portion 361. The photodetector 40e further has a slope bottom 43e and a substantially flat top 44e, so a thickness of the photodetector 40 e gradually increases from the front side 41e to the rear side 42e. A first distance d1 between the top of the front edge 331-1 and a bottom of the front side 41e is less than a second distance d2 between the top of the rear edge 331-4 and a bottom of the rear side 42e. In some embodiments, a ratio of the first distance d1 to the second distance d2 may be from about 1:5 to about 4:5. In some embodiments, the ratio of the first distance d1 to the second distance d2 may be from about 3:10 to about 7:10. In some embodiments, the ratio of the first distance d1 to the second distance d2 may be from about 2:5 to about 3:5.

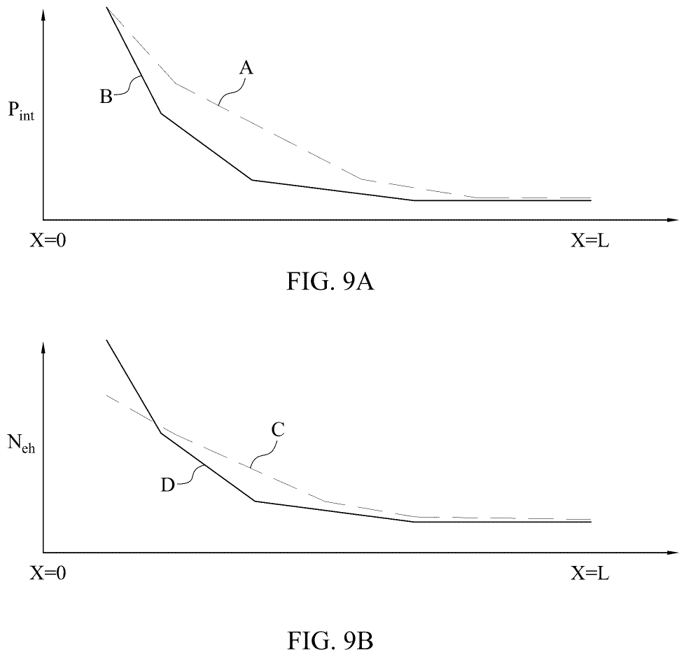

An incident light beam propagates along the first direction D1 and thus photodetector absorbs optical signal coming from the core region 31 of the waveguide 30, then generates electron and hole pairs that are proportional to optical intensity; the electron and hole pairs are collected by the waveguide region as current signal, which can be amplified by transimpedance amplifier of external electrical integrated circuit. Therefore, optical signal can be transferred to electrical signal. FIG. 9A shows a plot of an optical intensity as a function of length of a photodetector of a semiconductor structure. An optical intensity (Pint) would be highest at or near a front surface of a photodetector. A comparative photodetector may be embedded in a waveguide region with a consistent depth. That is, the comparative photodetector may have a flat top and a flat bottom parallel with each other and also parallel to a top of a cladding layer (i.e., a bottom of a waveguide region) and a top of a base layer. Therefore, the comparative photodetector can only receive optical signal from a front surface, so the optical intensity would decline steeply from the front surface of the comparative photodetector to a rear surface of the comparative photodetector (see Curve B in FIG. 9A). On the other hand, as shown in FIGS. 3 to 8, the photodetector 40-40e according to various aspects of the present disclosure has a stepwise, staircase or slope bottom and thus can absorb optical signal by only the front side 41-41e, but also the bottom. Therefore, the optical intensity would decline smoothly from the front side 41-41e to the rear side 42-42e (see Curve A in FIG. 9A).

In addition, a comparative photodetector may be deeply embedded in a waveguide region to increase a contact surface with the core region of a waveguide so as to absorb more optical signal. However, such high optical intensity would lead to high amount of electron and hole pair (Neh) as shown in FIG. 9B (see Curve D), resulting in undesired screening effect and impacting bandwidth. The screening effect would lead to lower electric field exerting on electrons and holes, causing the response time of electron and hole to electric field variation longer and thus decreasing processing speed. On the other hand, as shown in FIGS. 3 to 8, the photodetector 40-40e according to various aspects of the present disclosure has a first distance d1 (between the top of the front edge 331-1 and a bottom of the front side 41-41e) less than a second distance d2 (between the top of the rear edge 331-4 and a bottom of the rear side 42-42e). Therefore, the electron and hole pairs would not accumulate at the front side, but distribute to the photodetector 40-40e (see Curve C in FIG. 9B).

Accordingly, the photodetector 40-40e in accordance with the present disclosure is embedded shallowly near the front edge 331-1 of the first base portion 331 to achieve high speed capability, and deeply near the rear edge 331-4 of the first base portion 331 to achieve high power capability. The photodetector 40-40e of the present disclosure is applicable to high performance computing, tele-communication, data-communication, microwave photonics, and optical sensing.

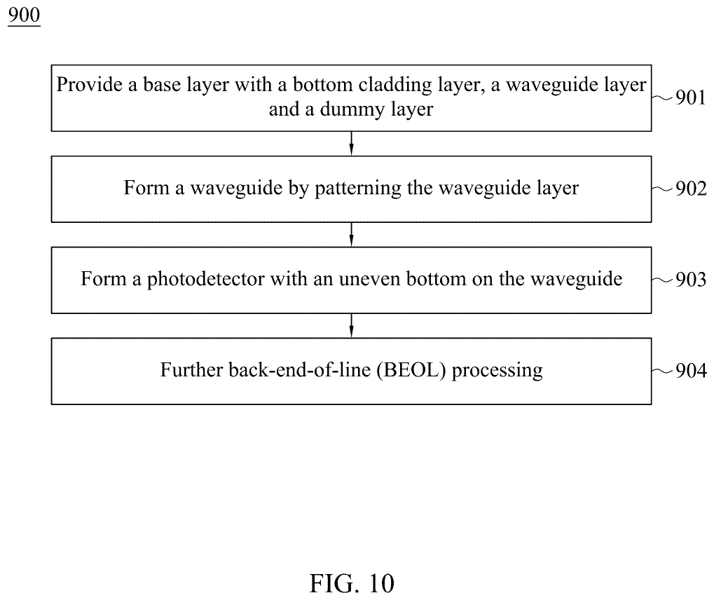

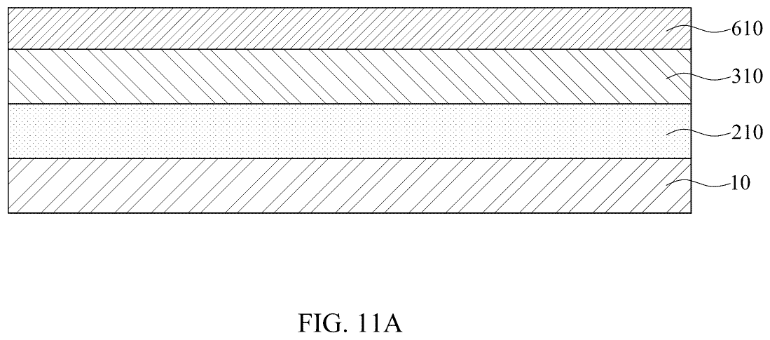

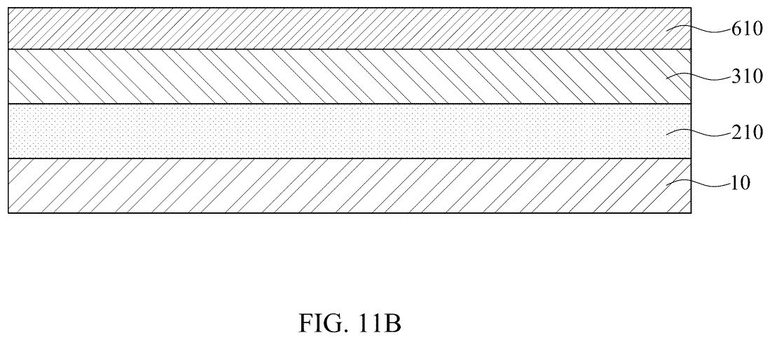

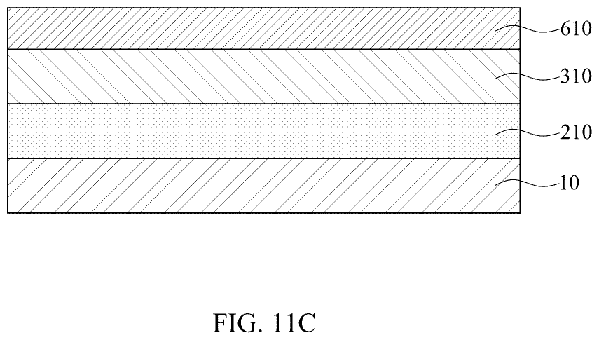

FIG. 10 is a flowchart representing a method 900 for forming a semiconductor structure according to various aspects of the present disclosure. In some embodiments, the method 900 for forming the semiconductor structure includes a number of operations (901, 902, 903 and 904). The method 900 for forming the semiconductor structure will be further described according to one or more embodiments. It should be noted that the operations of the method 900 may be rearranged or otherwise modified within the scope of the various aspects. It should further be noted that additional processes may be provided before, during, and after the method 900, and that some other processes may be only briefly described herein. FIGS. 11 to 25 are diagrammatic perspective views illustrating various stages in the method 900 for forming the semiconductor structure according to aspects of one or more embodiments of the present disclosure. 11A, 12A, 13A, 14A, 15A, 16A, 17A, 18A, 19A, 20A, 21A, 22A, 23A, 24A and 25A are cross-sectional views of the semiconductor structure corresponding to the cross-section along line A-A′ shown in FIG. 1; 11B, 12B, 13B, 14B, 15B, 16B, 17B, 18B, 19B, 20B, 21B, 22B, 23B, 24B and 25B are cross-sectional views of the semiconductor structure corresponding to the cross-section along line B-B′ shown in FIG. 1; and 11C, 12C, 13C, 14C, 15C, 16C, 17C, 18C, 19C, 20C, 21C, 22C, 23C, 24C and 25C are cross-sectional views of the semiconductor structure corresponding to the cross-section along line C-C′ shown in FIG. 1.

With reference to FIGS. 11A, 11B and 11C, the method 900 begins at operation 901 where a base layer 10 with a first cladding layer 210 as a bottom cladding layer, a waveguide layer 310 and a hard mask 610 is provided or received. The base layer 10 is usually a wafer made of a semiconducting material. Such materials can include silicon, for example in the form of crystalline Si or polycrystalline Si. The base layer 10 can also be made from other elementary semiconductors such as germanium or Al₂O₃ (sapphire), or may include a compound semiconductor such as silicon carbide (SiC), gallium nitride (GaN), gallium arsenide (GaAs), indium arsenide (InAs), and indium phosphide (InP), or from other materials such as glass, a ceramic, or a dielectric material. The base layer 10 can be planarized through a chemical mechanical polishing (CMP) procedure.

The first cladding layer 210 can be formed over the base layer 10 and may be made of an insulation material including an oxide, such as silicon oxide, a nitride, such as silicon nitride, the like, or a combination thereof, which may be formed by a chemical vapor deposition (CVD) process, such as high-density plasma CVD (HDP-CVD), flowable chemical vapor deposition (FCVD), the like, or a combination thereof. Other insulation materials formed by any acceptable process may be used. In some embodiments, the insulation material is silicon oxide formed by FCVD. Although the first cladding layer 210 is illustrated as a single layer, some embodiments may utilize multiple layers. The first cladding layer 210 can be planarized through a chemical mechanical polishing (CMP) procedure.

The waveguide layer 310 is formed over the first cladding layer 210 before forming the hard mask 610. The waveguide layer 310 may include semiconductor material such as, for example but not limited thereto, silicon. The hard mask 610 is formed over the waveguide layer 310 and may include a nitride, such as silicon nitride (SiNₓ) (e.g., as Si₃N₄).

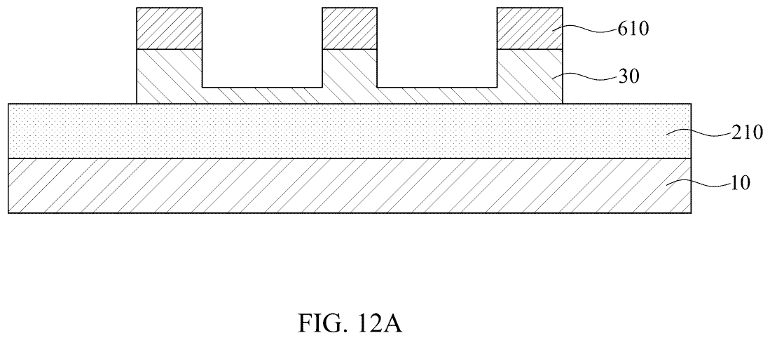

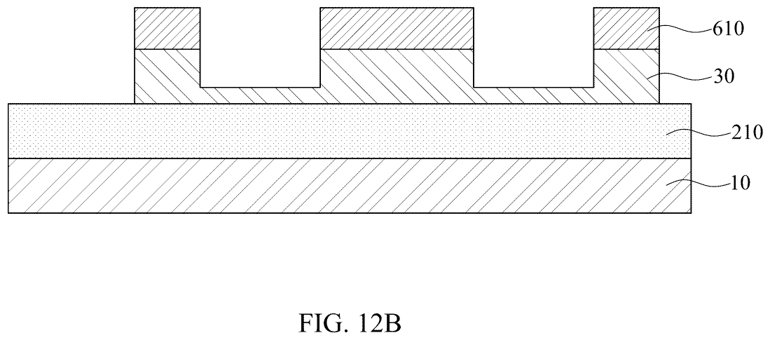

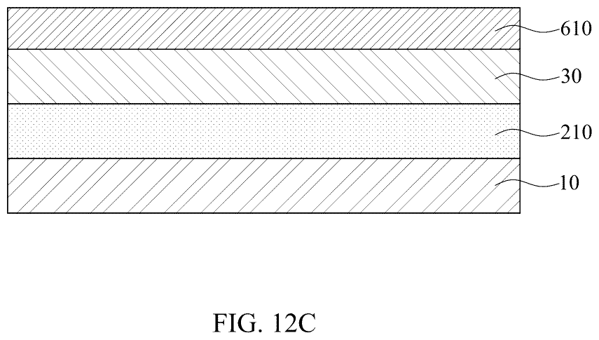

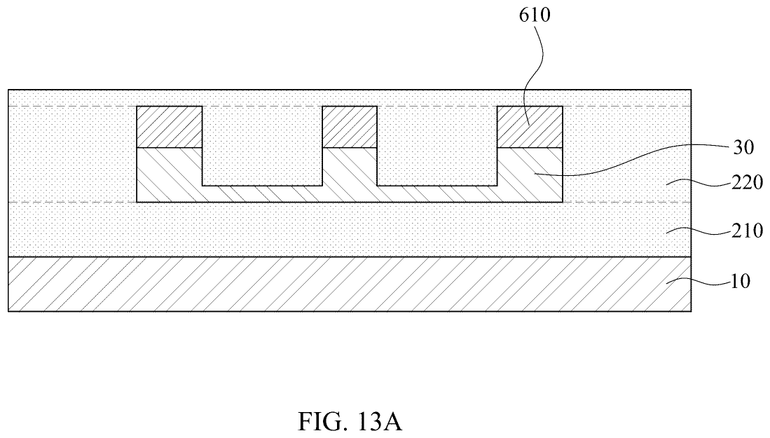

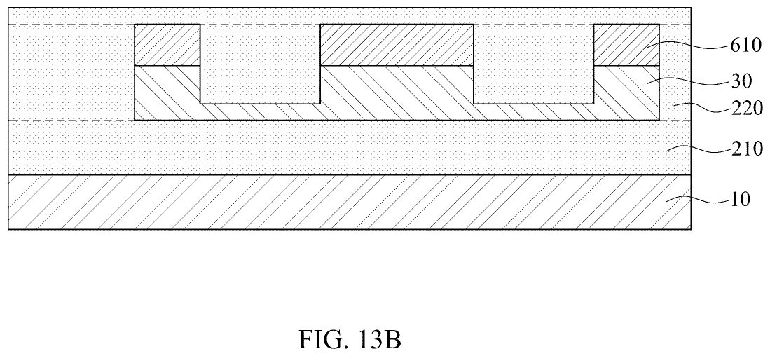

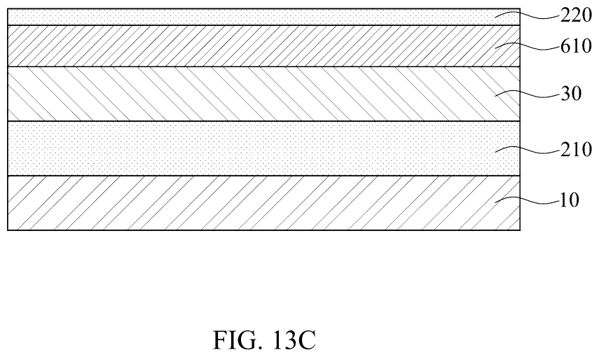

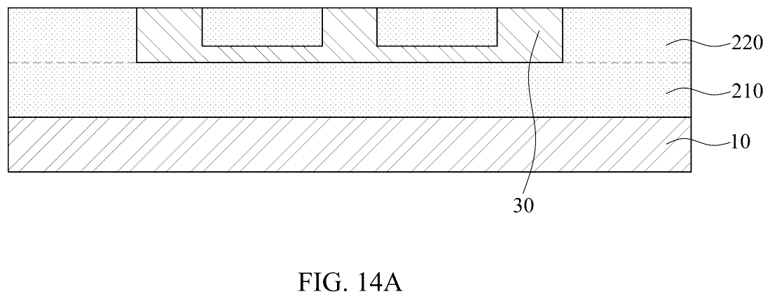

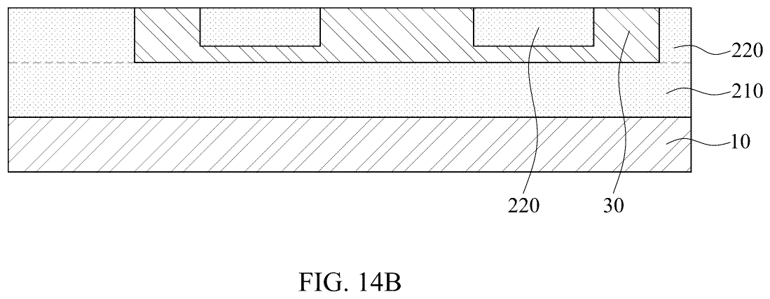

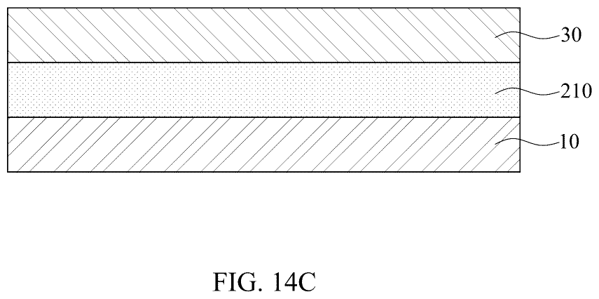

With reference to FIGS. 12A, 12B and 12C, the method 900 continues with operation 902 where a waveguide 30 is formed by patterning the waveguide layer 310 along with the hard mask 610. Further referring to FIGS. 13A, 13B and 13C, a second cladding layer 220 is formed on the first cladding layer 210 and over the waveguide 30 and the hard mask 610, so the first cladding layer 210 and the second cladding layer 220 constitute a cladding layer 20. Materials for forming the second cladding layer 220 may be identical to or different from those for forming the first cladding layer 210. Then, referring to FIGS. 14A, 14B and 14C, the hard mask 610 and the second cladding layer 220 formed on and surrounding the hard mask 610 are removed to expose the waveguide 30 from the second cladding layer 220. In some embodiments, such removal includes a chemical mechanical polishing (CMP) operation.

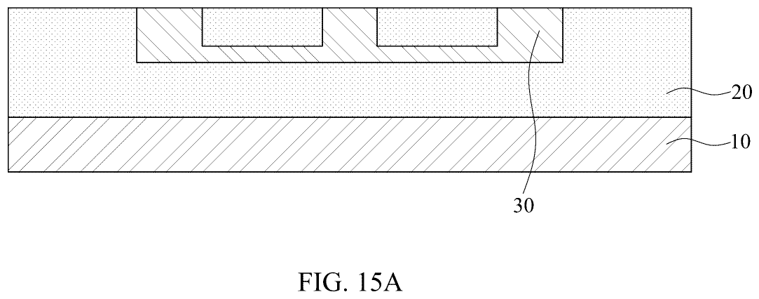

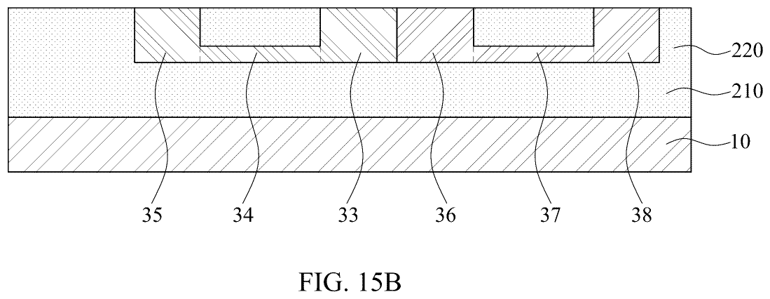

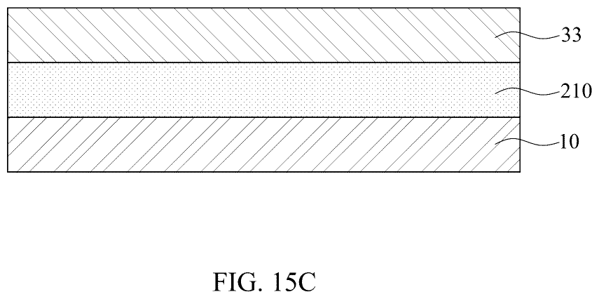

FIG. 15B shows a waveguide region 32 of the waveguide 30 is formed by implanting portion of the waveguide 30 into two different conductivity types, so that the waveguide region 32 comprises a first optical coupling portion 33 (also shown in FIG. 15C), a first slab portion 34, a first electrical coupling portion 35, a second optical coupling portion 36, a second slab portion 37 and a second electrical coupling portion 38 while the other portion of the waveguide 30 may remain unchanged as shown in FIG. 15A. The first optical coupling portion 33, the first slab portion 34, the first electrical coupling portion 35, the second optical coupling portion 36, the second slab portion 37 and the second electrical coupling portion 38 are strips parallel to each other. The first optical coupling portion 33, the first slab portion 34 and the first electrical coupling portion 35 comprise silicon and dopants with a first conductivity type. The second optical coupling portion 36, the second slab portion 37 and the second electrical coupling portion 38 have dopants with a second conductivity type.

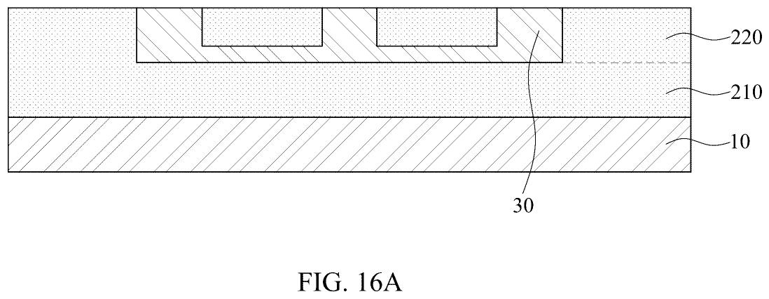

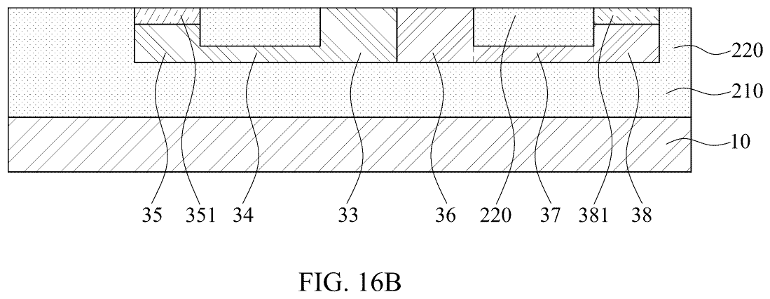

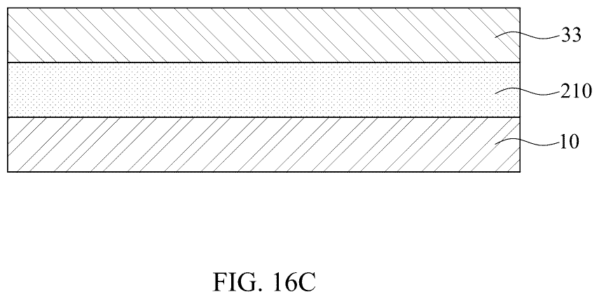

With reference to FIG. 16B, an upper region of the first electrical coupling portion 35 can be heavily doped with the first-conductivity-type dopants to form a first heavily doped region 351 and an upper region of the second electrical coupling portion 38 can be heavily doped with the second-conductivity-type dopants to form a second heavily doped region 381. The other portion of the waveguide 30 may remain unchanged as shown in FIGS. 16A and 16C.

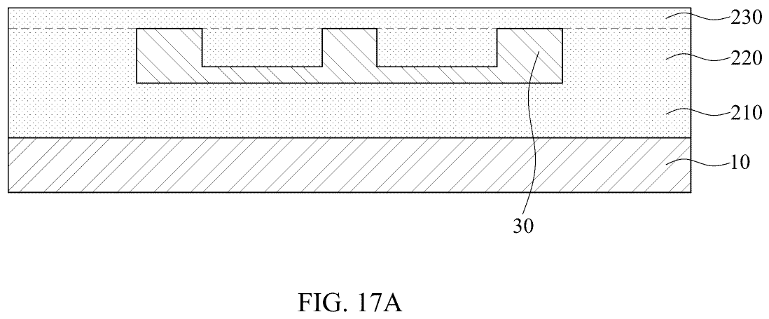

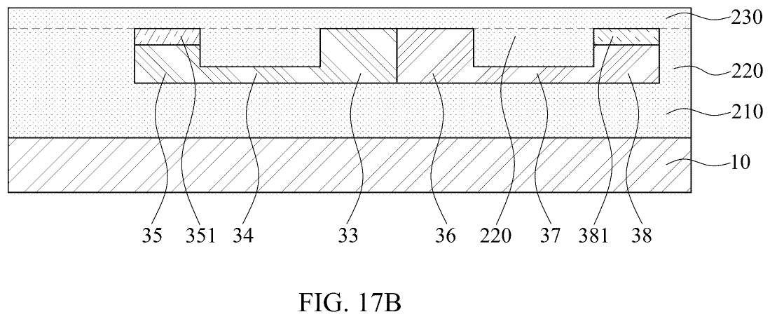

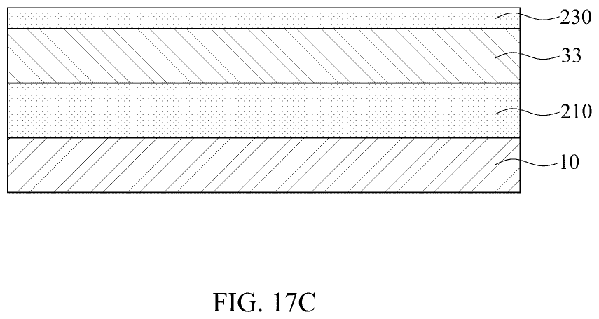

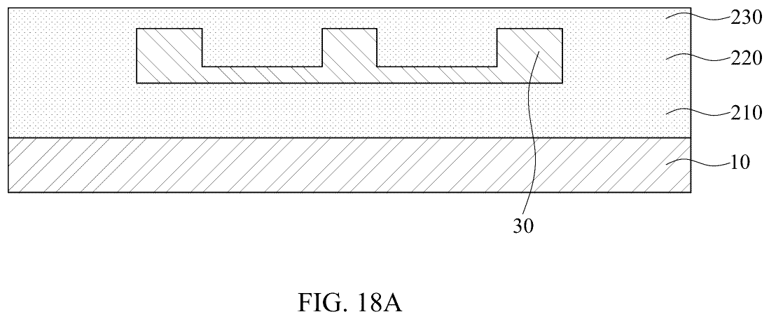

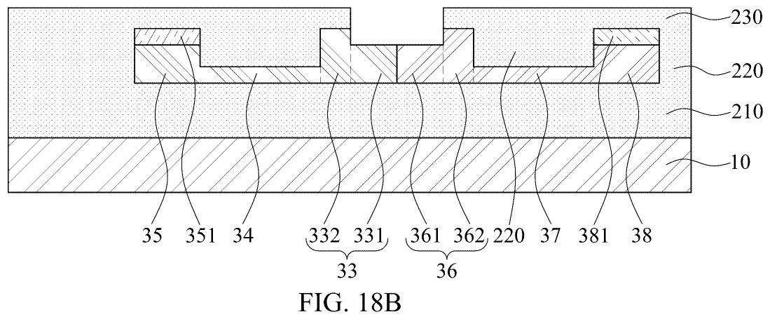

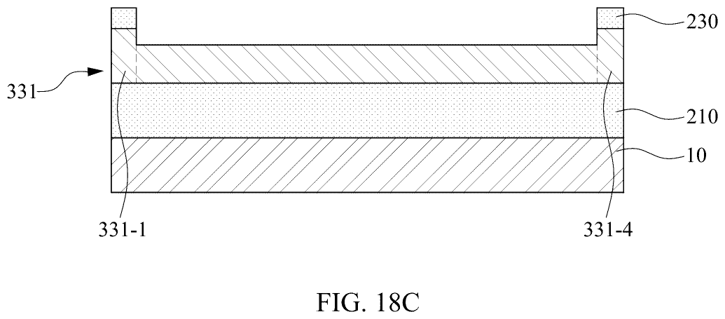

With reference to FIGS. 17A, 17B and 17C, a third cladding layer 230 can be applied onto the waveguide 30 and the second cladding layer 220. Materials for forming the third cladding layer 230 may be identical to or different from those for forming the first cladding layer 210 and/or those for forming the second cladding layer 220. Further, a location for forming a photodetector 40 is defined by removing a portion of the first optical coupling portion 33 and a portion of the second optical coupling portion 36 and the third cladding layer 230 formed thereon as shown in FIGS. 18B and 18C. Hence, the first optical coupling portion 33 has an L-shape cross-section from the front view and comprises a first base portion 331 and a first elongated portion 332 and the second optical coupling portion 36 has a reversed L-shape cross-section from the front view and comprises a second base portion 361 and a second elongated portion 362, in which the first base portion 331 and the second base portion 361 are exposed from the third cladding layer 230. The first base portion 331 is adjacent to and abuts the second base portion 361 as shown in FIG. 18B. From the cross-sectional side view as shown in FIG. 18C, the first base portion 331 of the first optical coupling portion 33 comprises a front edge 331-1, a middle portion and a rear edge 331-4. The middle portion is formed between the front edge 331-1 and the rear edge 331-4 and has a thickness less than a thickness of the front edge 331-1 and less than a thickness of the rear edge 331-4. The second base portion 361 of the second optical coupling portion 36 has a configuration substantially identical to or similar with the first base portion 331 of the first optical coupling portion 33, so FIG. 18C may also apply to showing the cross-sectional side view of the second base portion 361. Therefore, a drawing showing the cross-sectional side view of the second base portion 361 is omitted.

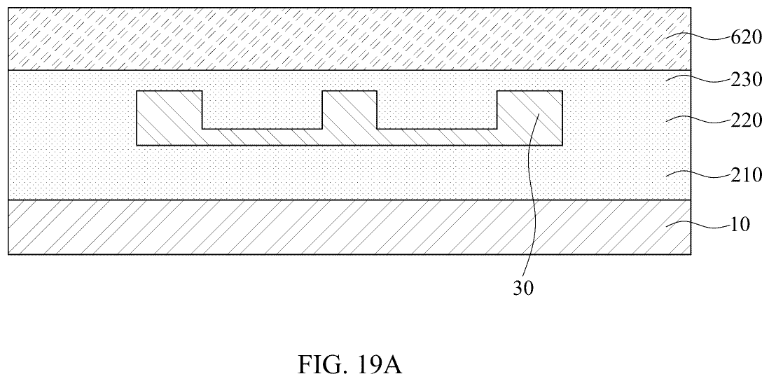

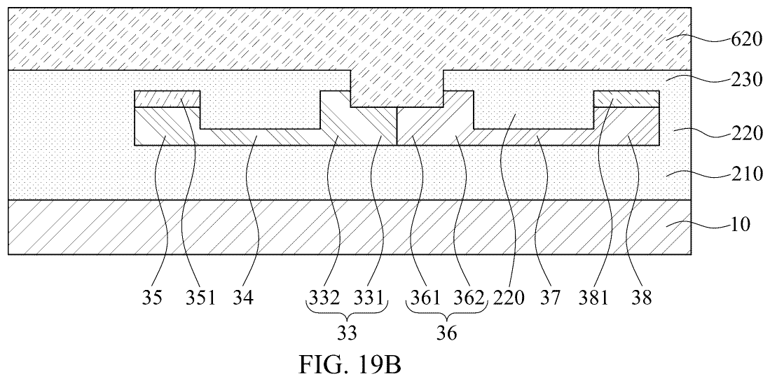

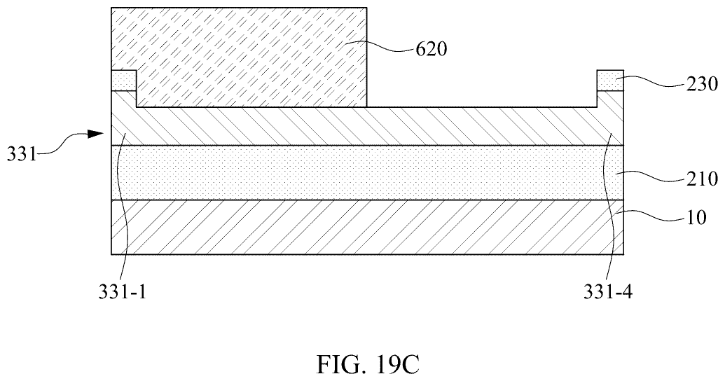

As shown in FIGS. 19A, 19B and 19C, a photoresist 620 is applied onto the third cladding layer 230 and partially applied on the exposed first base portion 331 and the second base portion 361 to expose rear parts of the middle portions of the first base portion 331 and the second base portion 361.

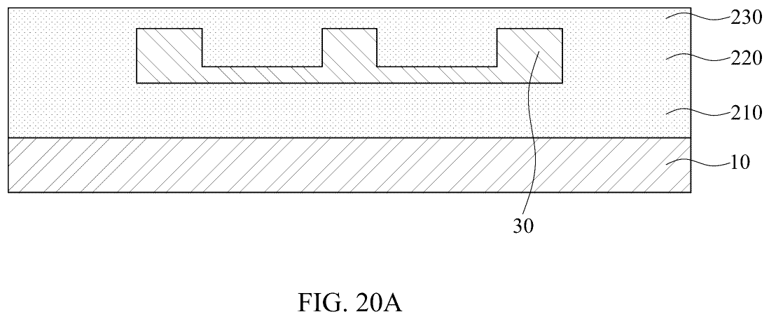

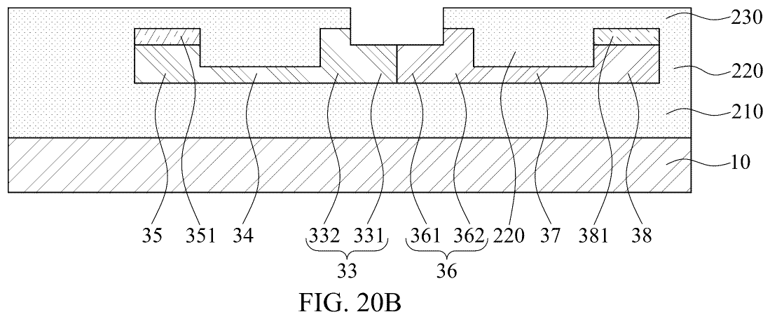

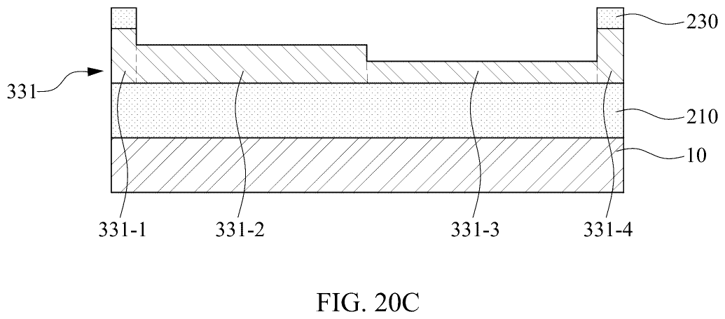

As shown in FIGS. 20A, 20B and 20C, the photoresist 620 can be removed after the rear parts of the middle portions of the first base portion 331 and the second base portion 361 are etched to a predetermined depth as shown in FIG. 20C. After etching, the middle portions of the first base portion 331 comprises a first middle portion 331-2 abutting the front edge 331-1 of the first base portion 331 and a second middle portion 331-3 abutting the rear edge 331-4. The thickness of the first middle portion 331-2 is greater than a thickness of the second middle portion 331-3.

In some another embodiments, more etching steps may be performed on the middle portions of the first base portion 331 and the second base portion 361 to form a staircase middle portion with a top in a staircase form, such as the staircase middle portion 331-5 shown in FIG. 4I. n some alternative embodiments, a single etching step using a mask with gradual transmission rate may be performed on the middle portions of the first base portion 331 and the second base portion 361 to form slope portions, such as the slope portion 331-6 as shown in FIG. 5.

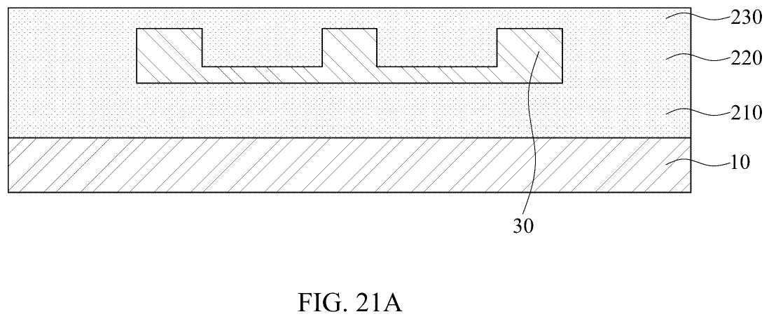

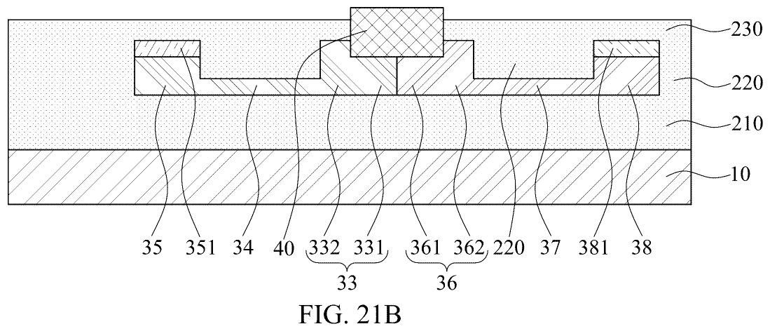

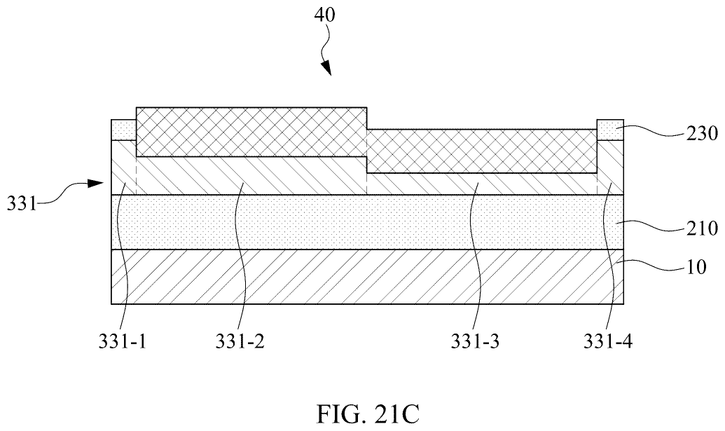

At operation 903, a photodetector 40 is formed over the waveguide region 32 of the waveguide 30 with an uneven bottom. The photodetector 40 is formed on the middle portion of the first base portion 331 and also on the middle portion of the second base portion 361 and comprises a front side 41 abutting the front edge 331-1 of the first base portion 331 and a front edge of the second base portion 361, a rear side 42 abutting the rear edge 331-4 of the first base portion 331 and a rear edge of the second base portion 361, and two sides respectively abutting the first elongated portion 332 and the second elongated portion 362. As shown in FIGS. 21B and 21C, the photodetector 40 may be conformally formed on the middle portions of the first base portion 331 and the second base portion 361 and comprise a front region 43 and a rear region 44. The front region 43 of the photodetector 40 is deposited on the first middle portion 331-2. The rear region 44 is extended from the front region 43 and is deposited on the second middle portion 331-3. A thickness of the front region 43 may be substantially identical to a thickness of the rear region 44. Therefore, the front region 43 and the rear region 44 are staircases corresponding to the staircase configuration formed by the first middle portion 331-2 and the second middle portion 331-3.

In some another embodiments, when the middle portions of the first base portion 331 and the second base portion 361 are staircase middle portions, such as the staircase middle portion 331-5 shown in FIG. 4, a photodetector 40a in the form of a staircase with multiple steps corresponding to the staircase top of the staircase middle portion 331-5 can be deposited on the middle portions of the first base portion 331. In some alternative embodiments, when the middle portions of the first base portion 331 and the second base portion 361 are slope portions, such as the slope portion 331-6 as shown in FIG. 5, a photodetector 40b with a slope bottom 43b and a slope top 44b can be deposited on the middle portions of the first base portion 331.

In some embodiments, after the formation of a photodetector on the waveguide 30, a planarization (such as CMP) may be performed, so that a top of the photodetector 40c, 40d, and 40e may be a substantially flat, as shown in FIGS. 6 to 8. Therefore, the thickness of the photodetector 40c, 40d, and 40e can be gradually increased from the front side 41c, 41d and 41e to the rear side 42c, 42d and 42e. Accordingly, the photodetector 40-40e in accordance with the present disclosure can be embedded shallowly near the front edge 331-1 of the first base portion 331 to achieve high speed capability, and deeply near the rear edge 331-4 of the first base portion 331 to achieve high power capability.

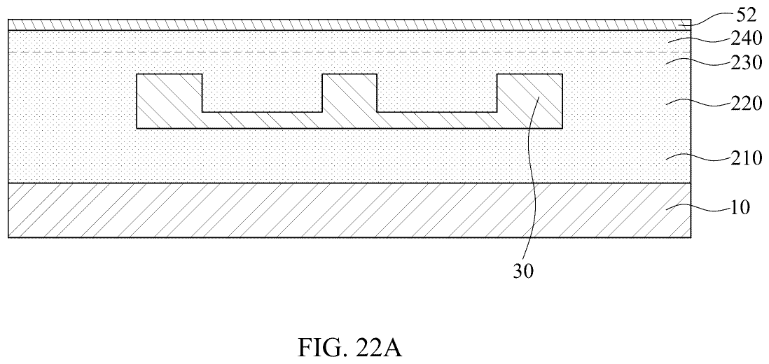

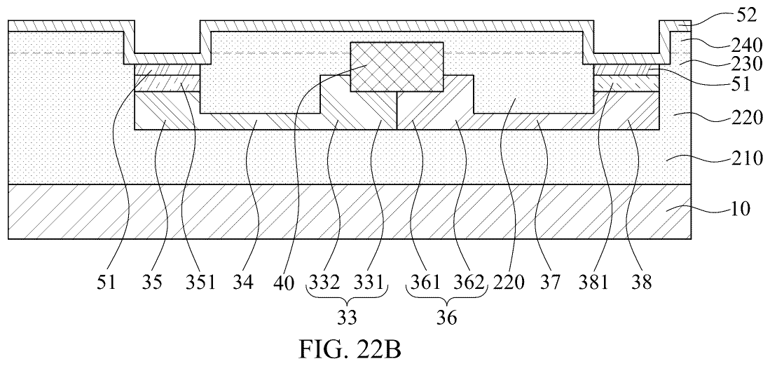

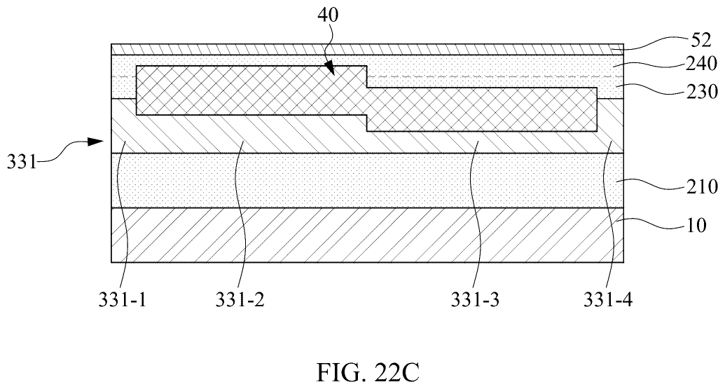

At operation 904, as shown in FIGS. 22 to 25, further back-end-of-line (BEOL) processing can be performed including applying a fourth cladding layer 240 over the third cladding layer 230 and the photodetector 40 and exposing tops of the first heavily doped region 351 and the second heavily doped region 381 by partially removing the third cladding layer 230 and the fourth cladding layer 240; forming a silicide layer 51 on the first heavily doped region 351 and the second heavily doped region 381 through applying metals on the tops of the first heavily doped region 351 and the second heavily doped region 381 and annealing the metal; depositing a contact etch stop layer (CESL) 52 onto the third cladding layer 230 and the waveguide 30 as shown in FIGS. 22A, 22B and 22C. The silicide layer 51 may be nickel silicide, copper silicide or other suitable silicide material.

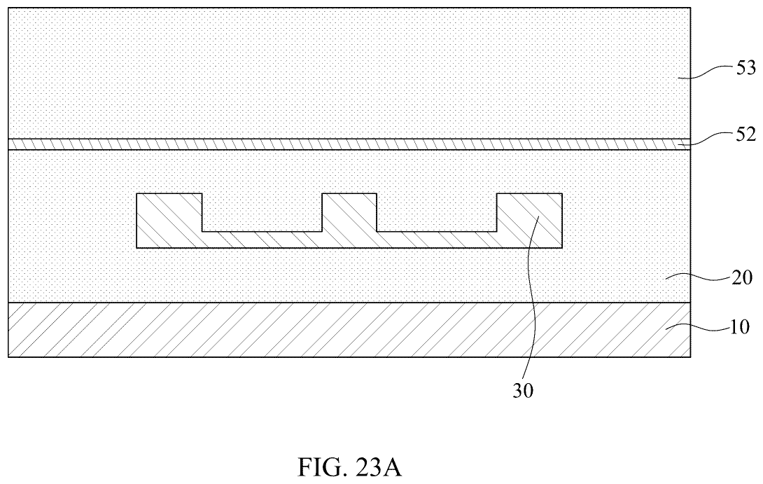

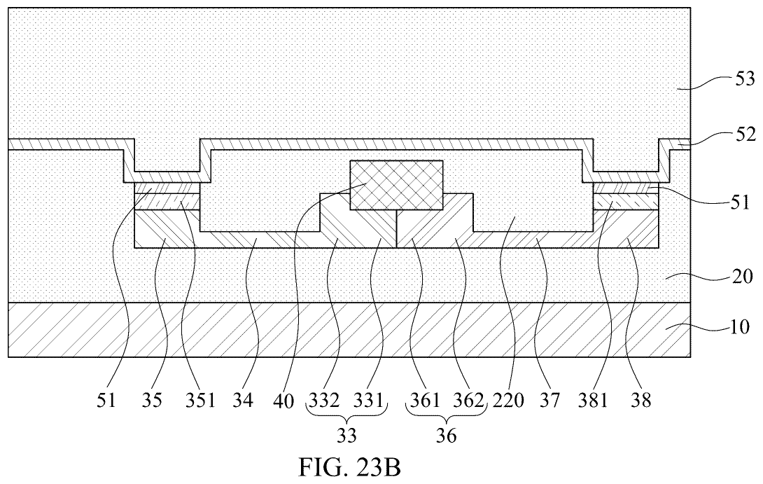

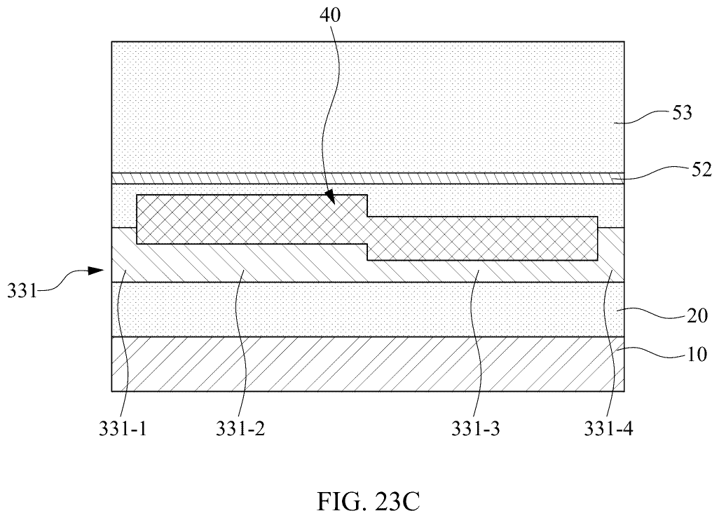

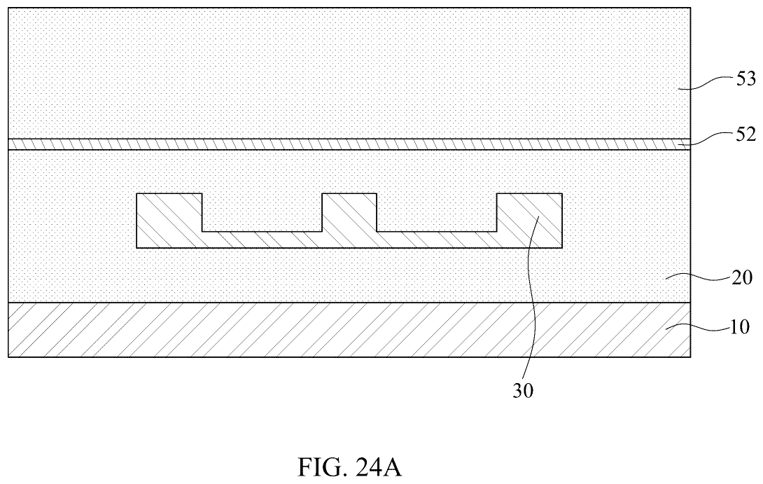

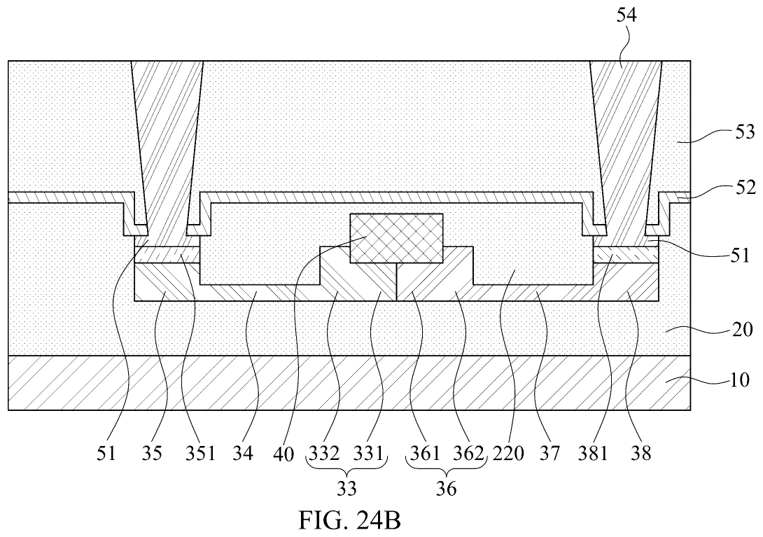

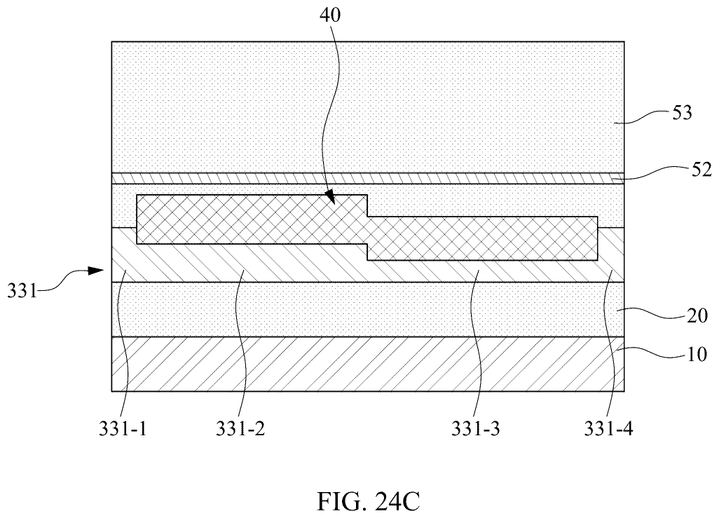

The BEOL processing can further include forming an interlayer dielectric layer (ILD layer) 53 on the CESL 52 as shown in FIGS. 23A, 23B and 23C; forming contacts 54 on the silicide structure 51 on the first heavily doped region 351 and the second heavily doped region 381 by partially removing the CESL 52 and the ILD layer 53 to form openings (not shown), filling the openings with conductive materials, and removing superfluous conductive materials as shown in FIGS. 24A, 24B and 24C.

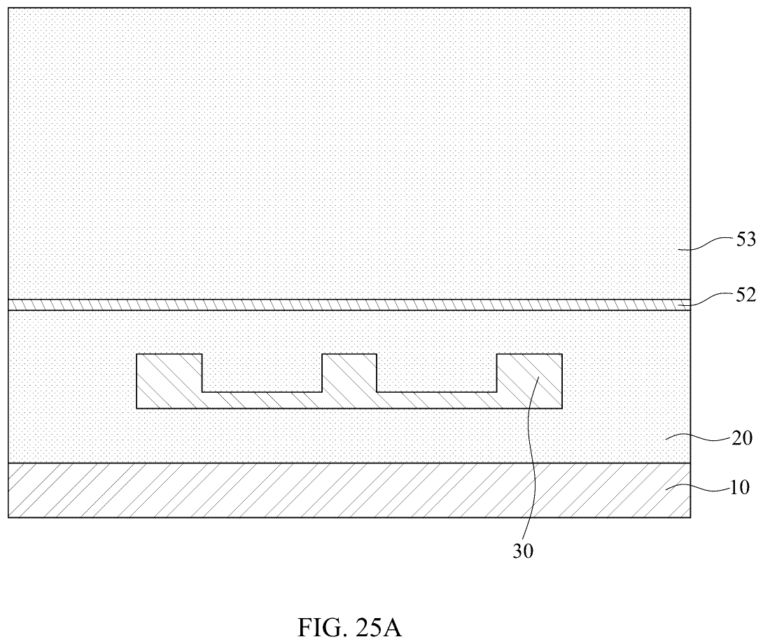

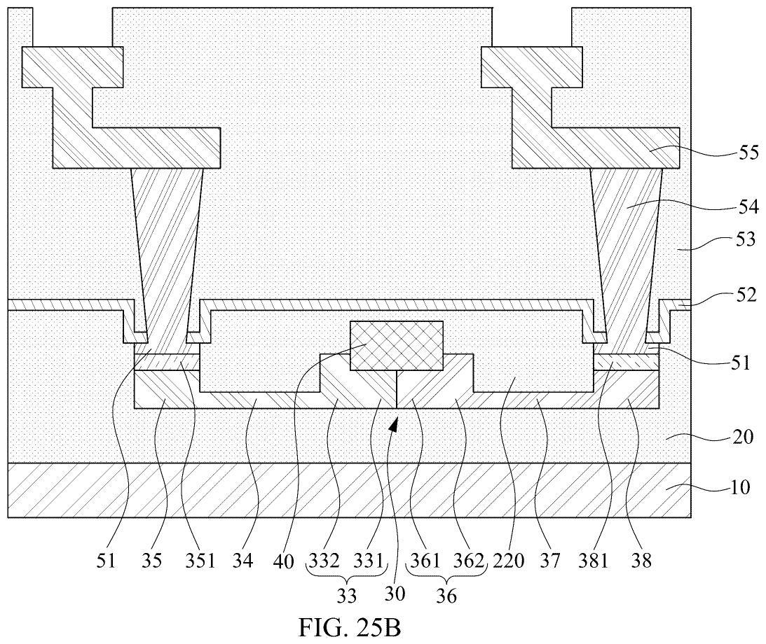

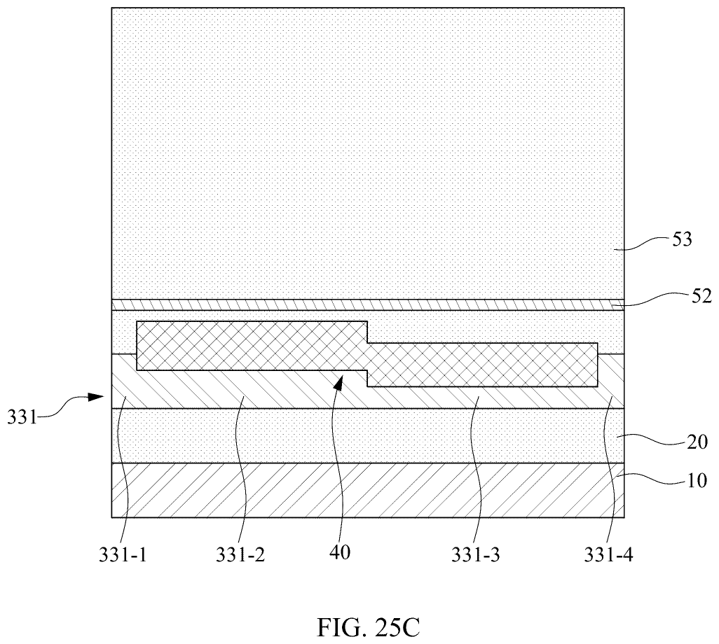

The BEOL processing can further include forming further metal lines 55 on the contacts 54 by forming an interlayer dielectric layer/inter-metal dielectric layer (ILD/IMD layer) 53 over the contacts 54, partially removing the further ILD/IMD layers to form trenches/vias (not shown), filling the trenches/vias with conductive materials, and removing superfluous conductive material as shown in FIGS. 25A, 25B and 25C. The ILD/IMD layer 53 may be, for example, silicon dioxide, silicon nitride, a low κ dielectric, some other dielectric, or a multi-layer film comprising a combination of the foregoing. As used herein, a low-κ dielectric is a dielectric with a dielectric constant κ less than about 3.9. In some embodiments, the material for forming the ILD/IMD layer 53 may be identical to the material for forming the cladding layer 20.

The photodetector 40-40e in accordance with the present disclosure is embedded shallowly near the front edge 331-1 of the first base portion 331, which can increase bandwidth to achieve high speed capability, and is embedded deeply near the rear edge 331-4 of the first base portion 331, which can increase saturation current to achieve high power capability. Thus, the semiconductor structure of the present disclosure can obtain high power and high speed capabilities so as to optimize the performance of the semiconductor structure.

In some embodiments, a method for forming a semiconductor structure comprises providing a waveguide layer over a base layer; forming a waveguide by patterning the waveguide layer so that the waveguide comprises: a core region; and a waveguide region extending from the core region along a first direction and comprising an optical coupling portion, wherein the optical coupling portion comprises a base portion sandwiched by two elongated portions along a second direction and the base portion comprising a front edge, a middle portion and a rear edge along the first direction, wherein the middle portion has a gradually decreased thickness from a region near the front edge to a region near the rear edge; and forming a photodetector on the middle portion of the base portion of the waveguide.

In some embodiments, a method for manufacturing a semiconductor structure, comprising: providing a waveguide layer over a base layer; patterning the waveguide layer to form a waveguide region of a waveguide on a base layer to form an optical coupling portion, wherein the optical coupling portion comprises a base portion sandwiched by two elongated portions along a first direction, wherein the base portion comprises a front edge, a middle portion and a rear edge along a second direction perpendicular to the first direction, applying a photoresist to partially cover a top of the middle portion of the base portion near the front edge; etching a portion of the middle portion of the base portion exposed from the photoresist to form a first middle portion abutting the front edge of the base portion and a second middle portion abutting the rear edge; removing the photoresist; conformally forming a photodetector on the first middle portion and the second middle portion of the base portion of the waveguide, wherein the photodetector comprises: a front region deposited on the first middle portion; and a rear region extended from the front region along the second direction and deposited on the second middle portion, wherein a thickness of the first middle portion is greater than a thickness of the second middle portion.

In some embodiments, a semiconductor structure comprises a waveguide region formed over a base layer and comprising an optical coupling portion, wherein the optical coupling portion comprises a base portion and two elongated portions, which are strips parallel to each other along a first direction, and wherein the base portion is formed between the two elongated portions and comprises a front edge, a middle portion and a rear edge along a second direction perpendicular to the first direction; a photodetector formed on the middle portion of the base portion and between the two elongated portions of the waveguide region and comprising: a front side abutting the front edge of the base portion; and a rear side abutting the rear edge of the base portion, wherein the middle portion of the base portion abuts the two elongated portions of the waveguide region, and wherein a first distance between a top of the front edge of the base portion of the waveguide region and a bottom of the front side of the photodetector is different from a second distanced between a top of the rear edge of the base portion of the waveguide region and a bottom of the rear side of the photodetector, and wherein a ratio of the first distance to the second distanced is from about 1:5 to about 4:5.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method for manufacturing a semiconductor structure, comprising:
providing a waveguide layer over a base layer;
forming a waveguide by patterning the waveguide layer so that the waveguide comprises:
a core region; and
a waveguide region extending from the core region along a first direction and comprising an optical coupling portion, wherein the optical coupling portion comprises a base portion sandwiched by two elongated portions along a second direction perpendicular to the first direction, wherein the base portion comprises a front edge, a middle portion and a rear edge along the first direction, wherein the middle portion has a gradually decreased thickness from a region near the front edge to a region near the rear edge; and
forming a photodetector on the middle portion of the base portion of the waveguide.

2. The method of claim 1, wherein the photodetector comprises:
a front side abutting the front edge of the base portion; and
a rear side abutting the rear edge of the base portion,
wherein a first distance between a top of the front edge of the base portion and a bottom of the front side of the photodetector is less than a second distance between a top of the rear edge of the base portion and a bottom of the rear side of the photodetector, and
wherein a ratio of the first distance to the second distance is from about 1:5 to about 4:5.

3. The method of claim 1, wherein the middle portion of the base portion of the optical coupling portion is formed by conducting two or more etching steps to form a top in a staircase form, and wherein the photodetector has a staircase bottom.

4. The method of claim 1, wherein the middle portion of the base portion of the optical coupling portion is formed by conducting a single etching step using a mask with gradual transmission rate to form a top with a slope; and wherein the photodetector has a slope bottom.

5. The method of claim 2, wherein after forming the photodetector, the method further comprises planarizing a top of the photodetector, so that the photodetector has a substantially flat top.

6. The method of claim 2, wherein the photodetector has a constant thickness from the front side to the rear side or has a gradually increased thickness from the front side to the rear side.

7. A method for manufacturing a semiconductor structure, comprising:
providing a waveguide layer over a base layer;
patterning the waveguide layer to form a waveguide region of a waveguide on the base layer, and to form an optical coupling portion, wherein the optical coupling portion comprises a base portion sandwiched by two elongated portions along a first direction, wherein the base portion1 comprises a front edge, a middle portion and a rear edge along a second direction perpendicular to the first direction,
applying a photoresist to partially cover a top of the middle portion of the base portion near the front edge;
etching a portion of the middle portion of the base portion exposed from the photoresist to form a first middle portion abutting the front edge of the base portion and a second middle portion abutting the rear edge;
removing the photoresist;
conformally forming a photodetector on the first middle portion and the second middle portion of the base portion of the waveguide, wherein the photodetector comprises:
a front region deposited on the first middle portion; and
a rear region extending from the front region along the second direction and deposited on the second middle portion,
wherein a thickness of the first middle portion of the base portion is greater than a thickness of the second middle portion.

8. The method of claim 7, wherein the first middle portion and the second middle portion are staircases with stepwisely decreased thicknesses.

9. The method of claim 7, wherein a thickness of the front region of the photodetector is substantially identical to a thickness of the rear region of the photodetector.

10. The method of claim 7, wherein the steps of applying the photoresist to partially cover the top of the middle portion, etching a portion of the middle portion and removing the photoresist are repeated to form at least one additional middle portion with a thickness greater than a thickness of the second middle portion and less than a thickness of the first middle portion.

11. The method of claim 7, wherein after forming the photodetector, the method further comprises planarizing a top of the photodetector, so that the photodetector has a substantially flat top, and a thickness of the front region of the photodetector is less than a thickness of the rear region of the photodetector.

12. The method of claim 7, wherein a ratio of a length of the front region of the photodetector along the second direction to a length of the rear region of the photodetector along the second direction ranges from about 1:5 to about 4:5.

13. The method of claim 7, wherein the photodetector comprises:
a front side abutting the front edge of the base portion; and
a rear side abutting the rear edge of the base portion,
wherein a first distanced1 between a top of the front edge of the base portion and a bottom of the front side of the photodetector is less than a second distance between a top of the rear edge of the base portion and a bottom of the rear side of the photodetector, and
wherein a ratio of the first distanced1 to the second distance is from about 1:5 to about 4:5.

14. A semiconductor structure, comprising:
a waveguide region formed over a base layer and comprising an optical coupling portion, wherein the optical coupling portion comprises a base portion and two elongated portions, which are strips parallel to each other along a first direction, and wherein the base portion is formed between the two elongated portions and comprises a front edge, a middle portion and a rear edge along a second direction perpendicular to the first direction;
a photodetector formed on the middle portion of the base portion and between the two elongated portions of the waveguide region and comprising:
a front side abutting the front edge of the base portion; and
a rear side abutting the rear edge of the base portion,
wherein the middle portion of the base portion abuts the two elongated portions of the waveguide region, and
wherein a first distanced1 between a top of the front edge of the base portion of the waveguide region and a bottom of the front side of the photodetector is different from a second distance between a top of the rear edge of the base portion of the waveguide region and a bottom of the rear side of the photodetector, and
wherein a ratio of the first distance to the second distance is from about 1:5 to about 4:5.

15. The semiconductor structure of claim 14, wherein the top of the front edge of the base portion is substantially coplanar with the top of the rear edge of the base portion.

16. The semiconductor structure of claim 14, wherein the middle portion of the base portion of the optical coupling portion comprises:
a front portion abutting the front side of the photodetector; and
a rear portion abutting the rear side of the photodetector,
wherein the photodetector is surrounded by the front portion and the rear portion of the middle portion of the base portion and the two elongated portions, and
wherein a thickness of the front portion is equal to or greater than a thickness of the rear portion.

17. The semiconductor structure of claim 14, wherein the photodetector is in a staircase bottom.

18. The semiconductor structure of claim 14, wherein the photodetector has a slope bottom.

19. The semiconductor structure of claim 14, wherein the photodetector has a staircase top, a slope top or a substantially flat top.

20. The semiconductor structure of claim 14, wherein the photodetector has a constant thickness from the front side to the rear side or has a gradually increased thickness from the front side to the rear side.
